(19) United States
(12) Patent Application Publication
(10) Pub. No.: US 2026/0354172 A1
(43) Pub. Date: Nov. 5, 2026

(54) SEMICONDUCTOR PACKAGE CAVITY FOR ELECTRICAL ISOLATION AND THERMAL DISSIPATION

(71) Applicant: TEXAS INSTRUMENTS INCORPORATED, Dallas, TX (US)

(72) Inventors: Rongwei ZHANG, Plano, TX (US); Enis TUNCER, Dallas, TX (US)

(21) Appl. No.: 19/195,390

(22) Filed: Apr. 30, 2025

(51) Int. Cl. H10W 40/22; H10P 14/60; H10P 50/00; H10P 54/00; H10W 70/40; H10W 70/69; H10W 72/00; H10W 72/50; H10W 74/01; H10W 90/00

(52) U.S. Cl. CPC H10W 40/22; H10P 14/6336; H10P 50/00; H10P 54/00; H10W 70/417; H10W 70/424; H10W 70/69; H10W 74/016; H10W 90/00; H10W 72/536; H10W 72/5363; H10W 72/5445; H10W 72/5449; H10W 72/884; H10W 90/738; H10W 90/756

(57) ABSTRACT

In examples, a semiconductor package includes a die attach pad and a semiconductor member having a bottom surface attached to the die attach pad, a top surface opposite the bottom surface, and a cavity. The semiconductor package also includes an insulative layer in the cavity and on at least a portion of the top surface, and a semiconductor die inside the cavity and attached to the insulative layer by a die attach material.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such integrated circuits on a wafer is called fabrication. After wafer fabrication, the wafer is cut into multiple pieces, called semiconductor dies, with each die containing one or more of the integrated circuits. The cutting, or sawing, of the wafer into individual dies is called singulation. An individual die may then be attached to a substrate or die attach pad. The resulting structure is subsequently covered with a mold compound to produce a package.

### SUMMARY

In examples, a semiconductor package includes a die attach pad and a semiconductor member having a bottom surface attached to the die attach pad, a top surface opposite the bottom surface, and a cavity. The semiconductor package also includes an insulative layer in the cavity and on at least a portion of the top surface, and a semiconductor die inside the cavity and attached to the insulative layer by a die attach material.

In examples, a method for manufacturing a semiconductor package includes etching a semiconductor wafer to form a cavity, depositing an insulative layer on the semiconductor wafer, sawing the semiconductor wafer to produce a semiconductor member including the cavity, attaching the semiconductor member to a metal die attach pad using a first die attach material, attaching a semiconductor die to the semiconductor member inside the cavity using a second die attach material, attaching a bond wire to a device side of the semiconductor die and to a conductive terminal, and covering the metal die attach pad, the conductive terminal, the semiconductor member, the first and second die attach materials, the insulative layer, the semiconductor die, and the bond wire with a mold compound.

### BRIEF DESCRIPTION OF THE DRAWINGS

FIGS. 1A, 1B, 1C, and 1D are cross-sectional, top-down, profile, and perspective views of a semiconductor package including a cavity for electrical isolation and thermal dissipation, in accordance with various examples.

FIGS. 2A, 2B, 2C, and 2D are cross-sectional, top-down, profile, and perspective views of a semiconductor package including a cavity for electrical isolation and thermal dissipation, in accordance with various examples.

FIGS. 3A, 3B, 3C, and 3D are cross-sectional, top-down, profile, and perspective views of a semiconductor package including a cavity for electrical isolation and thermal dissipation, in accordance with various examples.

FIG. 4 is a flow diagram of a method for manufacturing a semiconductor package including a cavity for electrical isolation and thermal dissipation, in accordance with various examples.

FIGS. 5A, 5B, 5C, 5D, 5E, 5F, 5G, and 5H are a process flow depicting the manufacture of a semiconductor package including a cavity for electrical isolation and thermal dissipation, in accordance with various examples.

FIG. 6 is a block diagram of an electronic device including a semiconductor package having a cavity for electrical isolation and thermal dissipation, in accordance with various examples.

### DETAILED DESCRIPTION

In some applications, a semiconductor die should be electrically isolated from the die attach pad to which the semiconductor die is attached. An electrically insulative die attach material is useful to attach the semiconductor die to the die attach pad and to provide the aforementioned isolation. However, in some cases, the semiconductor die is sawn using a mechanical saw, which results in the accumulation of semiconductor debris at the periphery of the semiconductor die (an effect known as “chipping”). This semiconductor debris may collapse from the periphery of the semiconductor die to the underlying die attach pad, thus shorting the semiconductor die to the die attach pad and effectively bypassing the die attach material. When such a short occurs, the electrical isolation previously provided by the die attach material is lost. To mitigate the risk of such shorts caused by chipping, other semiconductor wafer dicing techniques may be useful (e.g., plasma, laser), as such dicing techniques tend to avoid producing semiconductor debris. However, irrespective of the type of dicing technique used, the die attach material has a low thermal conductivity. Accordingly, even if the risk of electrical short is reduced or eliminated, poor thermal conductivity remains a technical challenge.

This description presents various examples of a semiconductor package including a cavity for electrical isolation and thermal dissipation. More specifically, the semiconductor package includes an active semiconductor die including an integrated circuit that is capable of performing various operations, and the semiconductor package further includes a passive semiconductor member that omits such circuitry. The passive semiconductor member includes a cavity that is coated with an insulative layer (e.g., electrically insulative but thermally conductive), and the active semiconductor die is seated inside the cavity and is attached to the insulative layer by a die attach material that is highly electrically and thermally conductive. The passive semiconductor member is attached to a die attach pad by another instance of the electrically and thermally conductive die attach material. Each of the layers between the active semiconductor die and the die attach pad is thermally conductive, thereby facilitating heat dissipation through a bottom surface of the semiconductor package. Furthermore, the cavity in the passive semiconductor member contains the non-viscous die attach material and prevents the non-viscous die attach material from seeping downward and inadvertently forming electrical shorts with structures below the insulative layer. In this manner, electrical isolation is achieved. Further still, the presence of the cavity in the passive semiconductor member reduces the thickness of the semiconductor package relative to the thickness that would result if the cavity were omitted. This reduction in package thickness is achieved because the active semiconductor die is seated in a lower horizontal plane (i.e., within the cavity) than would otherwise be the case. Semiconductor packages described herein may have thicknesses in the 0.5 mm-1.0 mm range.

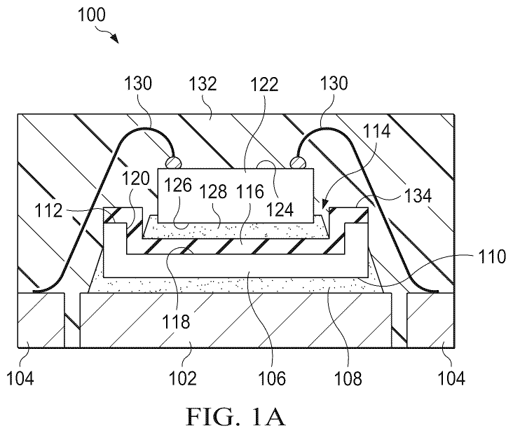

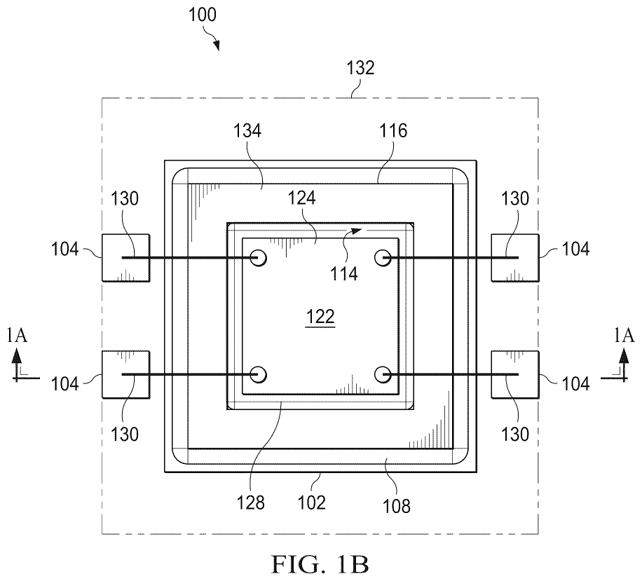

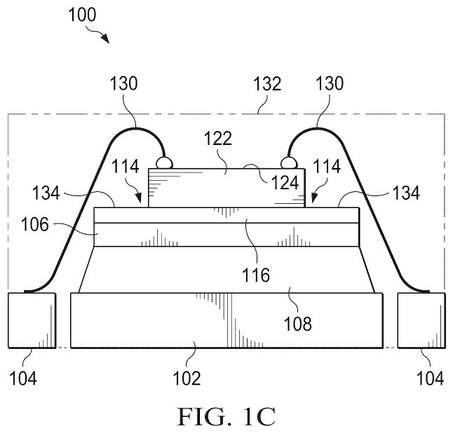

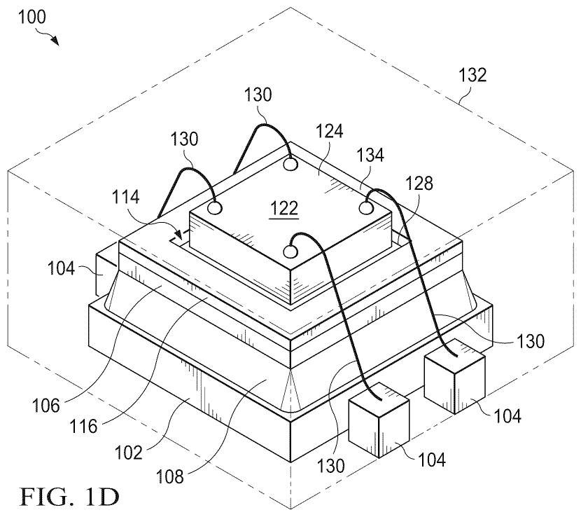

FIGS. 1A-1D are cross-sectional, top-down, profile, and perspective views of a semiconductor package including a cavity for electrical isolation and thermal dissipation, in accordance with various examples. In particular, FIGS. 1A-1D show a semiconductor package 100 (e.g., a quad flat no lead (QFN) package) including a die attach pad 102, conductive terminals 104, and a passive semiconductor (e.g., silicon) member 106 attached to the die attach pad 102 by a die attach material 108. The passive semiconductor member 106 has a bottom surface 110 contacting the die attach material 108 and a top surface 112. A cavity 114 is formed in the passive semiconductor member 106, and more specifically, in the top surface 112, meaning that the cavity 114 begins at the top surface 112 and extends toward the bottom surface 110 through some, but not all, of a thickness of the passive semiconductor member 106. The top surface 112 circumscribes the cavity 114. An insulative layer 116 contacts the top surface 112 and multiple surfaces of the cavity 114. In some examples, the insulative layer 116 contacts all of the top surface 112 and all surfaces of the cavity 114. Surfaces of the cavity 114 include a bottom surface 118 of the cavity 114 that extends parallel to the bottom surface 110, and four lateral surfaces 120 of the cavity 114 that extend perpendicular to the bottom surface 110. An active semiconductor (e.g., silicon) die 122 includes a device side 124 in which an integrated circuit is formed and a non-device side 126 opposite the device side 124. The active semiconductor die 122 is seated in the cavity 114, and more specifically, the active semiconductor die 122 is attached to the insulative layer 116 contacting the bottom surface 118 and/or the lateral surfaces 120 of the cavity 114 using a die attach material 128. Bond wires 130 attach the device side 124 to the conductive terminals 104. A mold compound 132 covers the various structures of the semiconductor package 100.

Although the passive semiconductor member 106 is described herein as comprising semiconductor material, other materials may be used. For example, glass, silicon carbide, and aluminum nitride may be useful for the passive semiconductor member 106.

The die attach materials 108 and 128 are highly thermally conductive. In examples, the die attach materials 108 and/or 128 include polymer materials (e.g., thermosetting polymer matrices, such as ATROX® 800HT7A), and the thermal conductivities of one or both of the die attach materials 108 and 128 is at least 75 Watts per meter-Kelvin (W/mK). Such materials may be applied, for example, using a time-pressure dispensing technique and have a thickness ranging from 10 microns to 100 microns, with a thickness below this range being disadvantageous because a thinner die attach material will have higher stress and thereby cause delamination, and with a thickness above this range being disadvantageous because non-homogenous sintering occurs within the material and results in delamination and cracking. In examples, the die attach materials 108 and/or 128 include polymer materials (e.g., thermosetting polymer matrices, such as ATROX® 800HT2VX), and the thermal conductivities of one or both of the die attach materials 108 and 128 is at least 175 W/mK. Such materials may be applied, for example, using a screen or stencil printing technique and have a thickness ranging from 10 microns to 100 microns, with a thickness below this range being disadvantageous because a thinner material risks delamination due to higher stress, and with a thickness above this range being disadvantageous because non-homogenous sintering occurs within the material and results in delamination and cracking.

The insulative layer 116 may comprise a passivation overcoat that includes an inorganic dielectric material (e.g., silicon nitride, silicon dioxide, or oxynitride, which may be deposited using techniques such as plasma-enhanced chemical vapor deposition (PECVD), low-pressure CVD, or atomic layer deposition), or a polymeric overcoat (e.g., polyimide, benzocyclobutene, or other epoxy-based materials, which may be deposited using techniques such as spray-coating). The insulative layer 116 has a thickness ranging from 1 microns to 20 microns, with a thickness below this range being disadvantageous because it is too thin to provide adequate isolation, and with a thickness above this range being disadvantageous because of a significantly negative impact on thermal performance, especially for lower thermal conductivity coatings. The insulative layer 116 has an electrical resistivity of at least 1×10¹² ohm-meters, with a value below this range being disadvantageous because it results in an unacceptable degree of current leakage.

The cavity 114 contains the die attach material 128 and prevents the die attach material 128 from seeping over an edge of the top surface 112, downward toward other electrically conductive structures (e.g., the passive semiconductor member 106, the die attach material 108, the die attach pad 102, the conductive terminals 104). The cavity 114 may have a volume that accommodates the die attach material 128 and a portion of the active semiconductor die 122 that is below a horizontal plane defined by a top surface 134 of a portion of the insulative layer 116 contacting the top surface 112. For example, a larger volume may be selected for the cavity 114 in response to a heavier and/or more voluminous active semiconductor die 122, because such a semiconductor die may be more likely to cause the die attach material 128 to flow out of the cavity 114. Similarly, a larger volume may be selected for the cavity 114 in response to a larger volume of the die attach material 128, because this larger volume of the die attach material 128 may be more likely to cause the die attach material 128 to flow out of the cavity 114. Likewise, a larger volume may be selected for the cavity 114 in response to a lower viscosity of the die attach material 128, because low viscosities may cause the die attach material 128 to more easily flow out of the cavity 114. Furthermore, the horizontal area of the top surface 112 may be selected based on one or more of the foregoing factors (e.g., volume or weight of the active semiconductor die 122, volume of the die attach material 128, viscosity of the die attach material 128), as well as the volume of the cavity 114. This is because the top surface 112 operates as a backup safety measure to prevent the die attach material 128 from reaching and seeping over an outer edge of the top surface 112 in the event that the die attach material 128 flows out of the cavity 114. The larger the horizontal area of the top surface 112, the more difficult for the die attach material 128 to reach and seep over an outer edge of the top surface 112. Accordingly, the depth of the cavity 114 should be at least 50% of the semiconductor die 122 thickness, with a depth smaller than this range significantly increasing risk of die attach material overflow onto the top surface 112 and/or beyond an outer edge of the top surface 112, causing reliability challenges (e.g., electrical shorting). Additionally, to further mitigate the risk of the die attach material 128 reaching and seeping over an outer edge of the top surface 112, the viscosity of the die attach material 128 is chosen to be within the range 5,000 mPa-s to 50,000 mPa-s, with a viscosity below this range being disadvantageous because the risk of seepage over an outer edge of the top surface 112 is too significant under conventional manufacturing conditions, and with a viscosity above this range being disadvantageous because the die attach material 128 will not flow adequately to provide an even, planar adhesive with which the active semiconductor die 122 may be attached to the insulative layer 116. Due to one or more of the foregoing measures, a vertical gap separates the topmost portion of the die attach material 128 from a horizontal plane defined by the top surface 134.

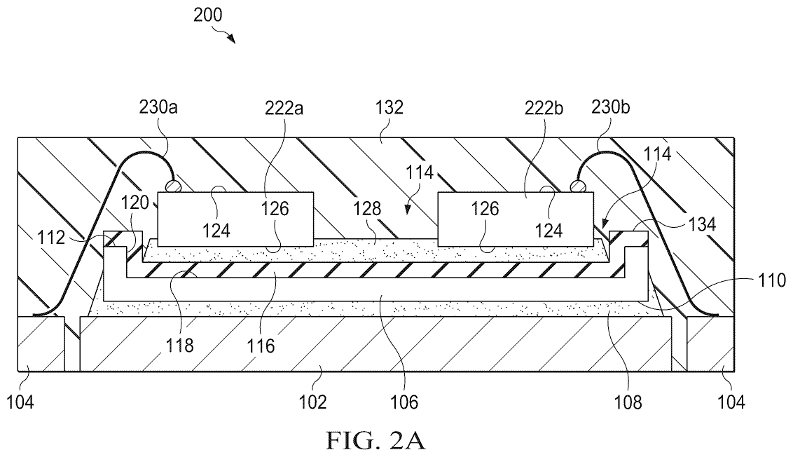

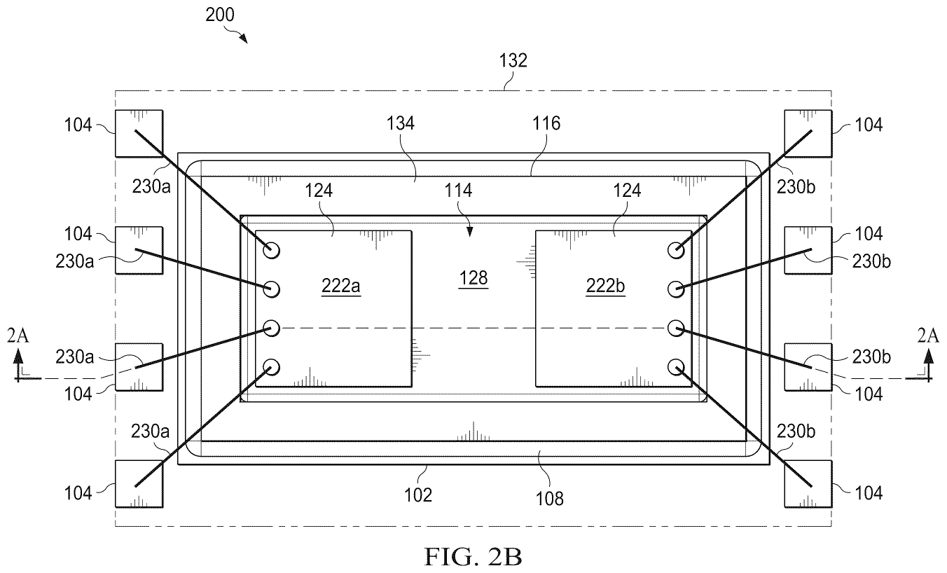

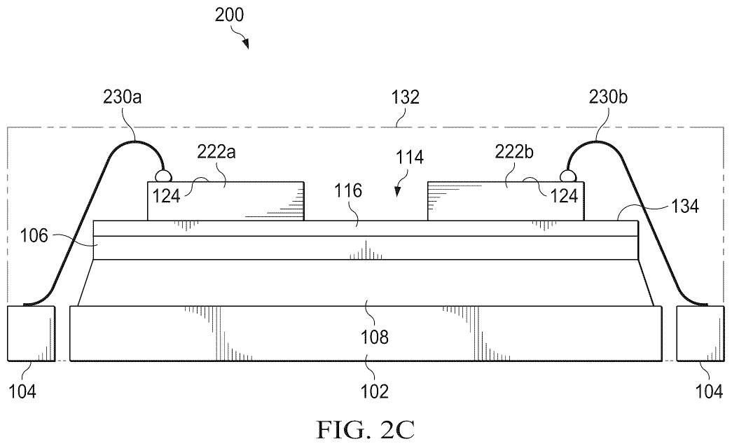

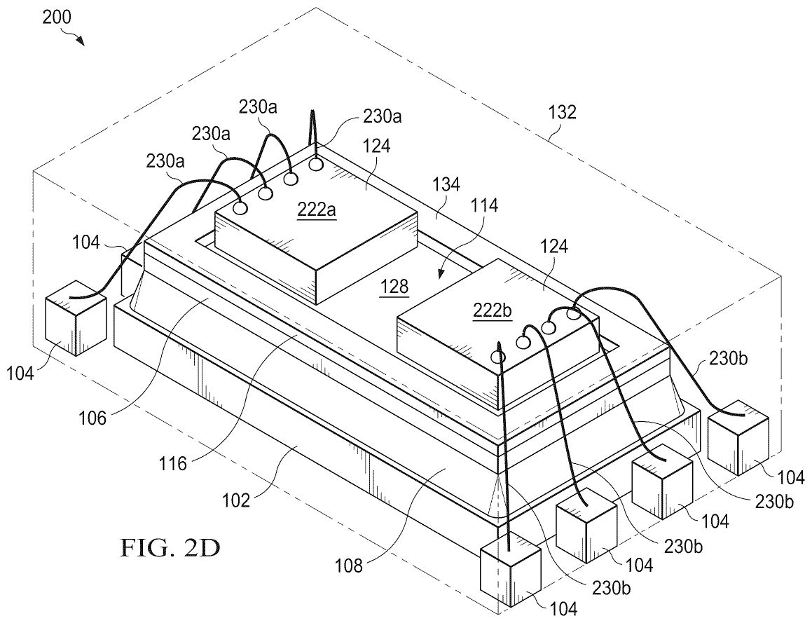

In some examples, the cavity 114 may include multiple, active semiconductor dies. FIGS. 2A-2D are cross-sectional, top-down, profile, and perspective views of a semiconductor package including a cavity for electrical isolation and thermal dissipation, in accordance with various examples. More particularly, FIGS. 2A-2D show a semiconductor package 200 that is identical to the semiconductor package 100 of FIGS. 1A-1D (and thus the description provided above for FIGS. 1A-1D also applies to FIGS. 2A-2D to the extent that FIGS. 2A-2D match FIGS. 1A-1D), except that the cavity 114 in the semiconductor package 200 includes multiple, active semiconductor dies 222a and 222b. Although the cavity 114 in the semiconductor package 200 is shown as including two active semiconductor dies 222a and 222b, in some examples, the cavity 114 may include three or more active semiconductor dies. The die attach material 128 attaches the active semiconductor dies 222a and 222b to a portion of the insulative layer 116 contacting the bottom surface 118 of the cavity 114. The cavity 114 in the semiconductor package 200 is larger than the cavity 114 in the semiconductor package 100 to accommodate the multiple semiconductor dies 222a and 222b and the additional volume of die attach material 128 used to attach the multiple semiconductor dies 222a and 222b to the passive semiconductor member 106. Each of the active semiconductor dies 222a and 222b has a device side in which an integrated circuit is formed and that faces away from the passive semiconductor member 106. A bond wire 230a is attached to the device side of the active semiconductor die 222a and to a first conductive terminal 104. A bond wire 230b is attached to the device side of the active semiconductor die 222b and to a second conductive terminal 104.

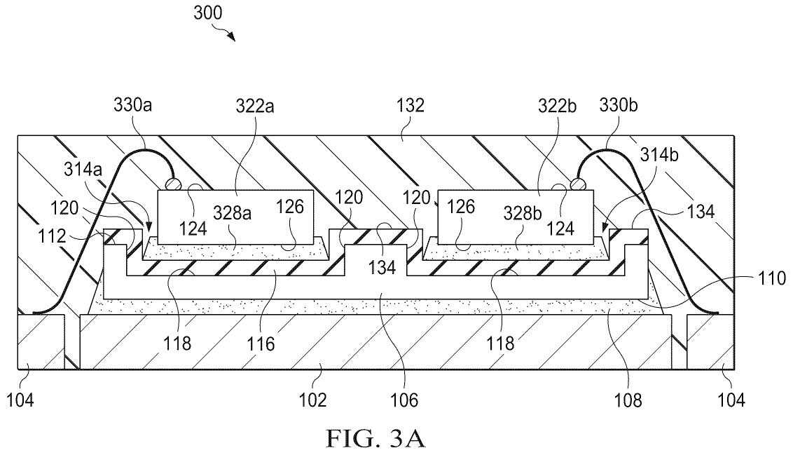

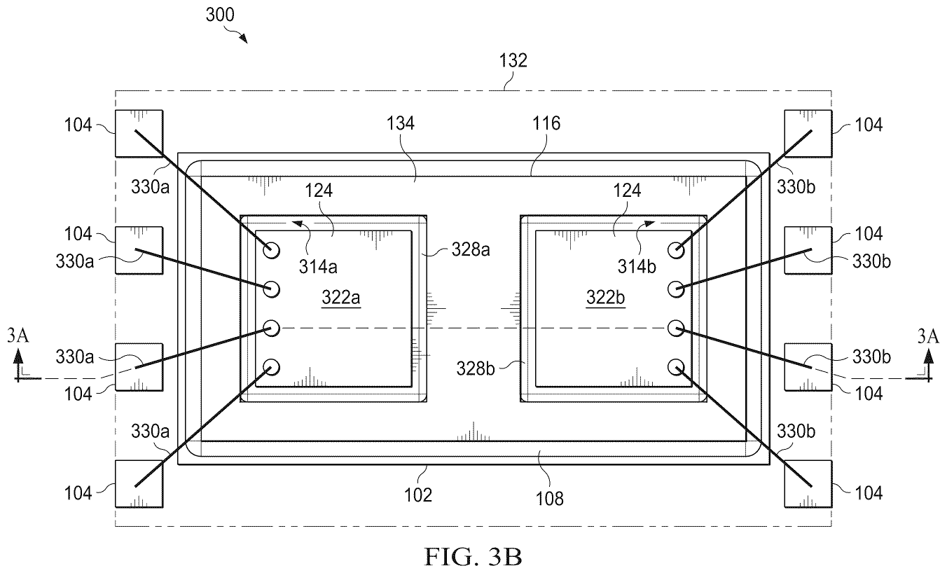

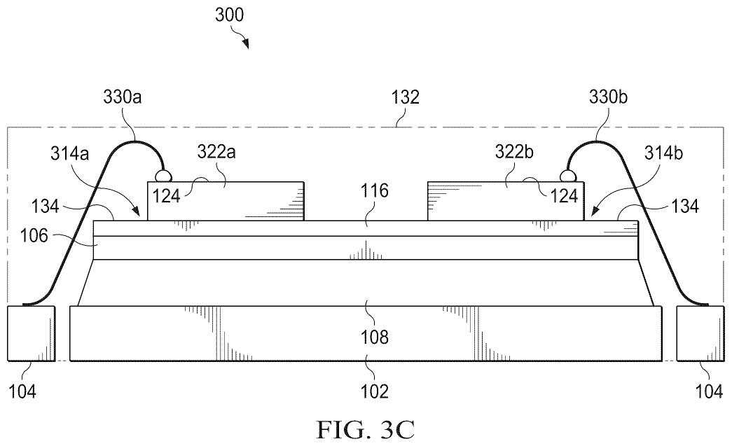

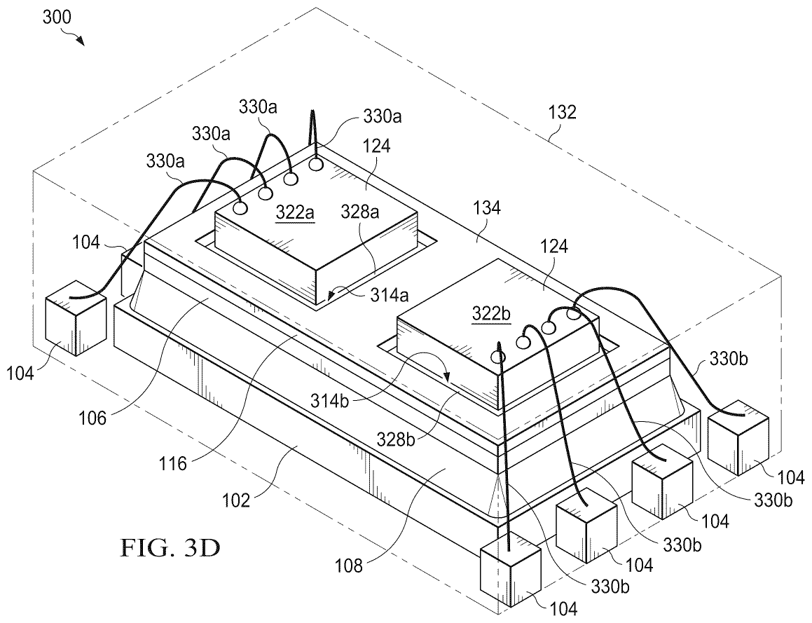

In some examples, a semiconductor package may include multiple, active semiconductor dies, with each active semiconductor die in a separate cavity. FIGS. 3A-3D are cross-sectional, top-down, profile, and perspective views of a semiconductor package including a cavity for electrical isolation and thermal dissipation, in accordance with various examples. More particularly, FIGS. 3A-3D show a semiconductor package 300 that is identical to the semiconductor package 100 of FIGS. 1A-1D (and thus the description provided above for FIGS. 1A-1D also applies to FIGS. 3A-3D to the extent that FIGS. 3A-3D match FIGS. 1A-1D), except that the semiconductor package 300 includes multiple cavities 314a and 314b in the passive semiconductor member 106, and a different active semiconductor die 322a and 322b is seated inside each of the cavities 314a and 314b, respectively. The description provided above for the cavity 114 in FIGS. 1A-1D also applies to each of the cavities 314a and 314b. The description provided above for each of the active semiconductor dies 122 also applies to each of the active semiconductor dies 322a and 322b. The insulative layer 116 covers multiple (e.g., all) surfaces of each of the cavities 314a and 314b, such as the floors and lateral walls of the cavities 314a and 314b. A die attach material 328a attaches the semiconductor die 322a to the insulative layer 116 in the cavity 314a, and a die attach material 328b attaches the active semiconductor die 322b to the insulative layer 116 in the cavity 314b. A topmost portion of the die attach material 328a is separated from a horizontal plane defined by the top surface 134 by a vertical gap. This vertical gap has the same physical features as the vertical gap described above with reference to FIGS. 1A-1D, and thus is not repeated here. Similarly, a topmost portion of the die attach material 328b is separated from a horizontal plane defined by the top surface 134 by a vertical gap. This vertical gap has the same physical features as the vertical gap described above with reference to FIGS. 1A-1D, and thus is not repeated here. Each of the active semiconductor dies 322a and 322b has a device side in which an integrated circuit is formed and that faces away from the passive semiconductor member 106. A bond wire 330a attaches the device side of the active semiconductor die 322a to a first conductive terminal 104, and a bond wire 330b attaches the device side of the active semiconductor die 322b to a second conductive terminal 104.

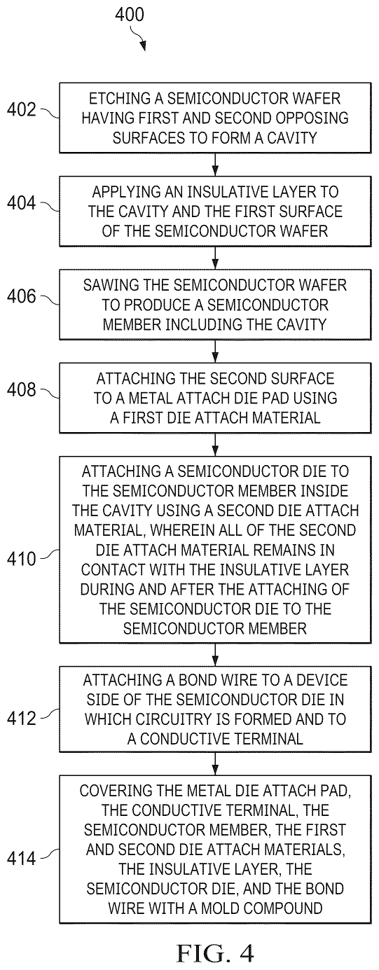

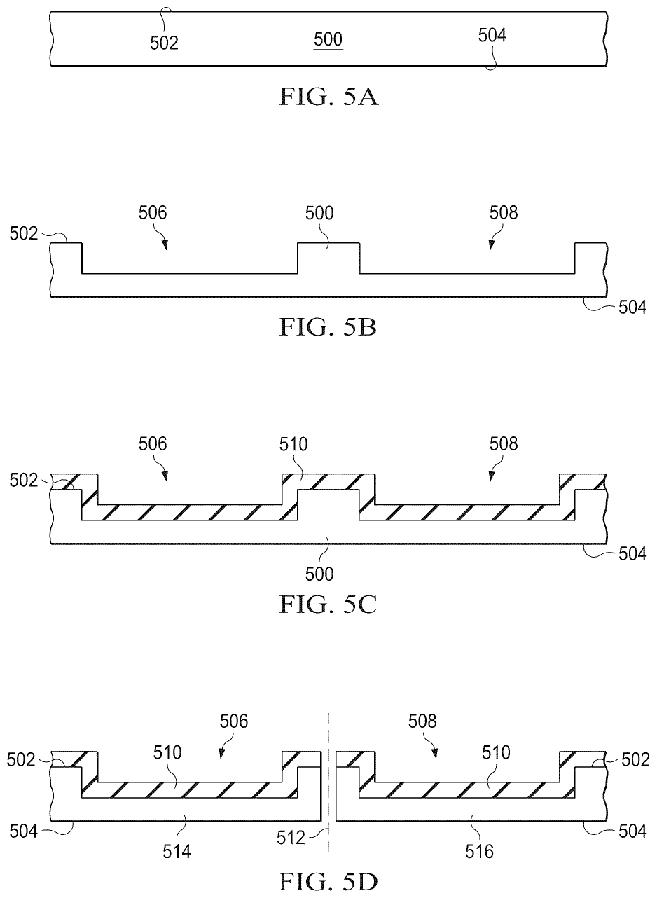

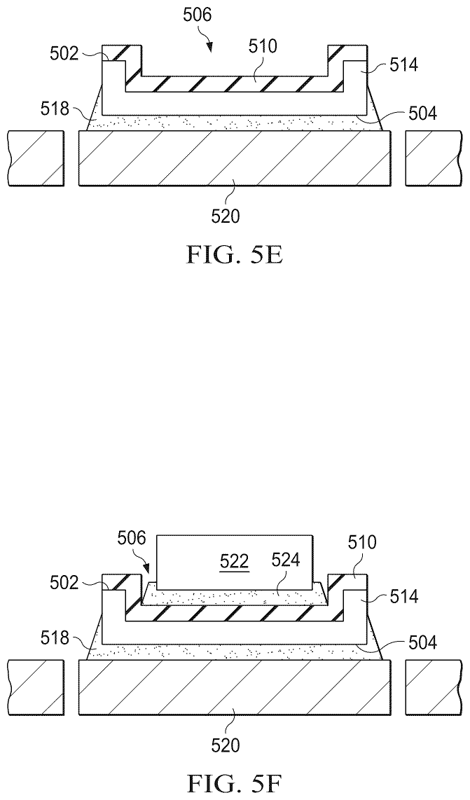

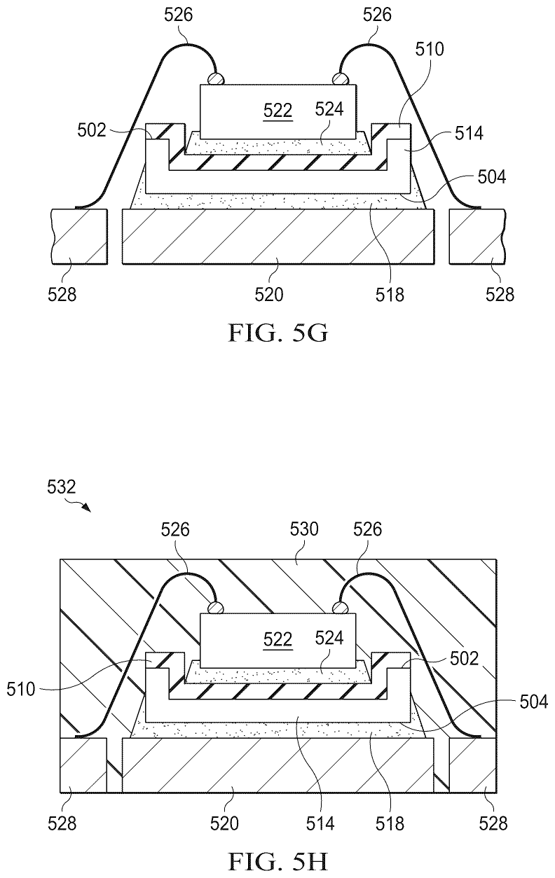

FIG. 4 is a flow diagram of a method 400 for manufacturing a semiconductor package including a cavity for electrical isolation and thermal dissipation, in accordance with various examples. FIGS. 5A-5H are a process flow depicting the manufacture of a semiconductor package including a cavity for electrical isolation and thermal dissipation, in accordance with various examples. Accordingly, FIGS. 4 and 5A-5H are now described in parallel with each other.

In examples, the method 400 includes etching a semiconductor wafer having first and second opposing surfaces to form a cavity (402). FIG. 5A is a cross-sectional view of a semiconductor wafer 500 having opposing surfaces 502 and 504. The semiconductor wafer 500 is passive, meaning that no circuitry is formed in the semiconductor wafer 500. FIG. 5B is a cross-sectional view of the semiconductor wafer 500 of FIG. 5A, except that cavities 506 and 508 have been etched into the surface 502 of the semiconductor wafer 500. Any suitable technique may be useful to form the cavities 506 and 508, such as deep reactive ion etching (DRIE), wet chemical etching, laser ablation, focused ion beam (FIB) milling, etc. The semiconductor wafer 500 is representative of the semiconductor material used to form the passive semiconductor member 106 (FIGS. 1A-1D, 2A-2D, and 3A-3D). The semiconductor wafer 500 may have the physical features attributed herein to the passive semiconductor member 106.

The method 400 includes applying an insulative layer to the cavity and the first surface of the semiconductor wafer (404). FIG. 5C is a cross-sectional view of the structure of FIG. 5B, except that an insulative layer 510 is applied to the surface 502 and to some or all surfaces of the cavities 506, 508. The insulative layer 510 is representative of the insulative layer 116 (FIGS. 1A-1D, 2A-2D, and 3A-3D) and may have the physical features attributed herein to the insulative layer 116. Various techniques may be useful to apply the insulative layer 510 to the surface 502 and to the various surfaces of the cavities 506 and 508, for example, PECVD, low-pressure CVD, spray-coating, etc.

The method 400 includes sawing the semiconductor wafer to produce a semiconductor member including the cavity (406). Any suitable technique may be useful, such as a mechanical or laser saw. FIG. 5D is a cross-sectional view of the structure of FIG. 5C, except that a numeral 512 indicates that the semiconductor wafer 500 has been sawn to produce multiple, separate, passive semiconductor members 514 and 516. The passive semiconductor members 514 and 516 are representative of the passive semiconductor member 106 (FIGS. 1A-1D, 2A-2D, and 3A-3D). Each of the passive semiconductor members 514 and 516 has a different insulative layer 510 as a result of the sawing.

The method 400 includes attaching the second surface to a metal die attach pad using a first die attach material (408). FIG. 5E is a cross-sectional view of the passive semiconductor member 514 of FIG. 5D, except that a die attach material 518 attaches the passive semiconductor member 514 to a die attach pad 520. The die attach material 518 is representative of the die attach material 108, and the die attach pad 520 is representative of the die attach pad 102 (FIGS. 1A-1D, 2A-2D, and 3A-3D). The die attach material 518 may be applied using any suitable technique, such as time-pressure dispensing techniques, stencil or screen printing, etc.

The method 400 includes attaching a semiconductor die to the semiconductor member inside the cavity using a second die attach material (410). In examples, all of the second die attach material remains in contact with the insulative layer during and after the attaching of the semiconductor die to the semiconductor member (410). FIG. 5F is a cross-sectional view of the structure of FIG. 5E, except that an active semiconductor die 522 is attached to the insulative layer 510 inside the cavity 506 using a die attach material 524. The die attach material 524 may be applied by any suitable technique, such as a time-pressure dispensing technique or a screen or stencil printing technique. The die attach material 524 is representative of the die attach material 128, and thus the description provided herein for the die attach material 128 also applies to the die attach material 524. As shown, all of the die attach material 524 remains in contact with the insulative layer 510 both during and after the attaching of the active semiconductor die 522 to the insulative layer 510. In some examples, the die attach material 524 remains entirely within the cavity 506 both during and after the attaching of the active semiconductor die 522 to the insulative layer 510. In other examples, the die attach material 524 flows out of the cavity 506 during and/or after the attaching of the active semiconductor die 522 to the insulative layer 510, but in such examples, the die attach material 524 does not reach the outer edge of the top surface of the passive semiconductor member 514 (i.e., the perimeter of the top surface of the insulative layer 510). The die attach material 524 is prevented from reaching this perimeter due to one or more of the volume of the cavity 506, the volume of the die attach material 524, the weight and/or volume of the active semiconductor die 522, the viscosity of the die attach material 524, and/or the area of the top surface of the passive semiconductor member 514 (i.e., the area of the portion of the insulative layer 510 that contacts the surface 502), as described above.

The method 400 includes attaching a bond wire to a device side of the semiconductor die in which circuitry is formed and to a conductive terminal (412). FIG. 5G is a cross-sectional view of the structure of FIG. 5F, except that bond wires 526 are attached to the device side of the active semiconductor die 522 and to conductive terminals 528.

The method 400 includes covering the metal die attach pad, the conductive terminal, the semiconductor member, the first and second die attach materials, the insulative layer, the semiconductor die, and the bond wire with a mold compound (414). FIG. 5H is a cross-sectional view of the structure of FIG. 5G, except that a mold compound 530 covers and contacts all remaining components of the completed semiconductor package 532, as shown.

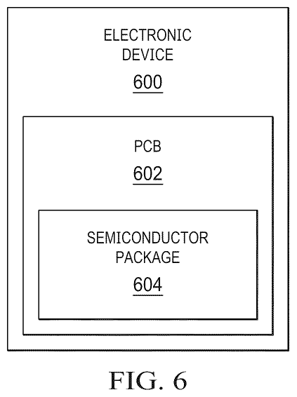

FIG. 6 is a block diagram of an electronic device including a semiconductor package having a cavity for electrical isolation and thermal dissipation, in accordance with various examples. More specifically, FIG. 6 shows an electronic device 600 including a printed circuit board (PCB) 602 to which a semiconductor package 604 is attached. The semiconductor package 604 is representative of the various semiconductor packages described herein, such as the semiconductor packages 100, 200, 300, and 532. The semiconductor package 604 may find application in, for example, a high-speed multiplexing/demultiplexing switch, a voltage level translator and bidirectional bus transceiver, a current shunt monitor, a power switch, a current sensor, etc. The scope of this disclosure is not limited to these or any other applications.

In this description, the term “attach” may cover connections, communications, or signal paths that enable a functional relationship consistent with this description. For example, if device A generates a signal to control device B to perform an action: (a) in a first example, device A is attached to device B by direct connection; or (b) in a second example, device A is attached to device B through intervening component C if intervening component C does not alter the functional relationship between device A and device B, such that device B is controlled by device A via the control signal generated by device A.

As used herein, the terms “conductive terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a die attach pad;
a semiconductor member having a bottom surface attached to the die attach pad, a top surface opposite the bottom surface, and a cavity;
an insulative layer in the cavity and on at least a portion of the top surface; and
a semiconductor die inside the cavity and attached to the insulative layer by a die attach material.

2. The semiconductor package of claim 1, further comprising a vertical gap between a topmost portion of the die attach material and a horizontal plane defined by a top surface of a portion of the insulative layer contacting the top surface of the semiconductor member.

3. The semiconductor package of claim 1, wherein the insulative layer comprises an inorganic dielectric material.

4. The semiconductor package of claim 1, wherein the insulative layer has a thickness ranging from 1 micron to 20 microns.

5. The semiconductor package of claim 1, wherein the die attach material has a thermal conductivity of at least 75 Watts per meter-Kelvin (W/mK).

6. The semiconductor package of claim 1, wherein the cavity has a volume that is greater than a volume of the die attach material combined with a volume of a portion of the semiconductor die that is below a horizontal plane defined by a top surface of a portion of the insulative layer contacting the top surface of the semiconductor member.

7. The semiconductor package of claim 1, wherein the die attach material is a first die attach material, further comprising a second die attach material between the die attach pad and the semiconductor member.

8. A semiconductor package, comprising:
a metal die attach pad;
a first die attach material contacting the metal die attach pad;
a semiconductor member having a first surface contacting the first die attach material, a second surface opposing the first surface, and a cavity, the cavity including cavity walls and a cavity floor;
an insulative layer contacting the second surface, the cavity walls, and the cavity floor;
a second die attach material contacting the insulative layer on the cavity walls and the cavity floor, a top surface of the second die attach material located below a horizontal plane defined by a top surface of a portion of the insulative layer contacting the second surface;
a semiconductor die having a device side and a non-device side opposing the device side, the non-device side contacting the second die attach material;
a bond wire attached to the device side of the semiconductor die and to a conductive terminal; and
a mold compound contacting the metal die attach pad, the first and second die attach materials, the semiconductor member, the insulative layer, the semiconductor die, the bond wire, and the conductive terminal.

9. The semiconductor package of claim 8, further comprising:
a second cavity in the semiconductor member, the second cavity including second cavity walls and a second cavity floor, the insulative layer contacting the second cavity floor and the second cavity walls; and
a second semiconductor die attached to the insulative layer on the second cavity walls and the second cavity floor by a third die attach material, a topmost portion of the third die attach material located below the horizontal plane.

10. The semiconductor package of claim 8, wherein the second surface circumscribes the cavity.

11. The semiconductor package of claim 8, wherein the cavity has a volume that is greater than a volume of the second die attach material combined with a volume of a portion of the semiconductor die that is below the horizontal plane.

12. The semiconductor package of claim 8, wherein the insulative layer comprises an inorganic dielectric material selected from the group consisting of silicon nitride, silicon dioxide, and oxynitride.

13. The semiconductor package of claim 8, wherein the insulative layer has a thickness ranging from 1 micron to 20 microns.

14. The semiconductor package of claim 8, wherein the second die attach material has a thermal conductivity of at least 75 Watts per meter-Kelvin (W/mK).

15. The semiconductor package of claim 8, further comprising a second semiconductor die in the cavity and contacting the second die attach material, the second semiconductor die having a second device side attached to a second conductive terminal by a second bond wire.

16. A method for manufacturing a semiconductor package, comprising:
etching a semiconductor wafer to form a cavity;
depositing an insulative layer on the semiconductor wafer;
sawing the semiconductor wafer to produce a semiconductor member including the cavity;
attaching the semiconductor member to a metal die attach pad using a first die attach material;
attaching a semiconductor die to the semiconductor member inside the cavity using a second die attach material;
attaching a bond wire to a device side of the semiconductor die and to a conductive terminal; and
covering the metal die attach pad, the conductive terminal, the semiconductor member, the first and second die attach materials, the insulative layer, the semiconductor die, and the bond wire with a mold compound.

17. The method of claim 16, wherein depositing the insulative layer comprises using a plasma-enhanced chemical vapor deposition (PECVD) or spray-coating technique.

18. The method of claim 16, wherein the insulative layer has a thickness ranging from 1 micron to 20 microns.

19. The method of claim 16, wherein a depth of the cavity is at least 50% of a thickness of the semiconductor die.

20. The method of claim 16, wherein, during attaching of the semiconductor die to the semiconductor member, the second die attach material fills the cavity and flows onto a portion of the insulative layer contacting a top surface of the semiconductor member without flowing past a perimeter of the top surface.
